(19) United States
(12) Patent Application Publication
(10) Pub. No.: US 2025/0146682 A1
(43) Pub. Date: May 8, 2025

(54) OUTDOOR UNIT

(71) Applicant: DAIKIN INDUSTRIES, LTD., Osaka (JP)

(72) Inventors: Yuji OGATA, Osaka (JP); Masahide FUJIWARA, Osaka (JP); Keito KOTERA, Osaka (JP); Narushige UEDA, Osaka (JP); Junichi HIROSE, Osaka (JP); Kazuhiro NAKATANI, Osaka (JP)

(21) Appl. No.: 19/012,301

(22) Filed: Jan. 7, 2025

Related U.S. Application Data
(63) Continuation of application No. PCT/JP2023/017063, filed on May 1, 2023.

(30) Foreign Application Priority Data
Jul. 8, 2022 (JP) 2022-110730

(51) Int. Cl. F24F 1/56

(52) U.S. Cl. CPC F24F 1/56

(57) ABSTRACT

An outdoor unit of an air conditioner includes a casing having an opening for maintenance, and a substrate disposed in the casing. The substrate includes a first surface on which an electric component is disposed, and a second surface facing the opening. The substrate includes a light transmitting region in which light is transmitted from the first surface toward the second surface when the second surface is viewed from a front, and a first light source provided on the first surface. The first light source is a surface mount LED that emits light toward the light transmitting region.

### CROSS-REFERENCE TO RELATED APPLICATIONS

This is a continuation of International Application No. PCT/JP2023/017063 filed on May 1, 2023, which claims priority under 35 U.S.C. § 119 (a) to Patent Application No. 2022-110730, filed in Japan on Jul. 8, 2022, all of which are hereby expressly incorporated by reference into the present application.

### BACKGROUND

### Technical Field

The present disclosure relates to an outdoor unit.

### Background Art

An outdoor unit of an air conditioner of Japanese Unexamined Patent Publication No. 2005-195209 includes a substrate having an LED for failure diagnosis provided on a mounting surface and includes a reflector that reflects light from the LED. The reflector is provided to reflect light of the LED toward an inspection port.

### SUMMARY

A first aspect is directed to an outdoor unit of an air conditioner, including a casing having an opening for maintenance, and a substrate disposed in the casing. The substrate includes a first surface on which an electric component is disposed, and a second surface facing the opening. The substrate includes a light transmitting region in which light is transmitted from the first surface toward the second surface when the second surface is viewed from a front, and a first light source provided on the first surface. The first light source is a surface mount LED that emits light toward the light transmitting region.

### BRIEF DESCRIPTION OF THE DRAWINGS

FIG. 1 is a piping system diagram of an air conditioner according to an embodiment.

FIG. 2 is a plan sectional view of a configuration of an outdoor unit.

FIG. 3 is a front sectional view of the configuration of the outdoor unit.

FIG. 4 is a longitudinal sectional view of a configuration of an electric component unit.

FIG. 5 is a partially enlarged view of a substrate as viewed from a pattern surface.

FIG. 6 is a side view of a surface mount LED mounted on the substrate.

FIG. 7 is a side view of two surface mount LEDs mounted on the substrate according to a variation.

FIG. 8 shows a surface mount LED according to another embodiment mounted on the substrate.

### DETAILED DESCRIPTION OF EMBODIMENT(S)

An embodiment of the present disclosure will be described with reference to the drawings. The following embodiment is a merely exemplary one in nature, and is not intended to limit the scope, application, or uses of the invention. Features of the embodiment, variations, and other examples described below can be combined or partially substituted within the range where the present invention can be embodied. In the drawings, the up and down, front and back, and left and right directions are indicated by arrows. Unless otherwise specified, directions such as up and down will be described in accordance with the directions indicated by these arrows.

### (1) CONFIGURATION OF AIR CONDITIONER

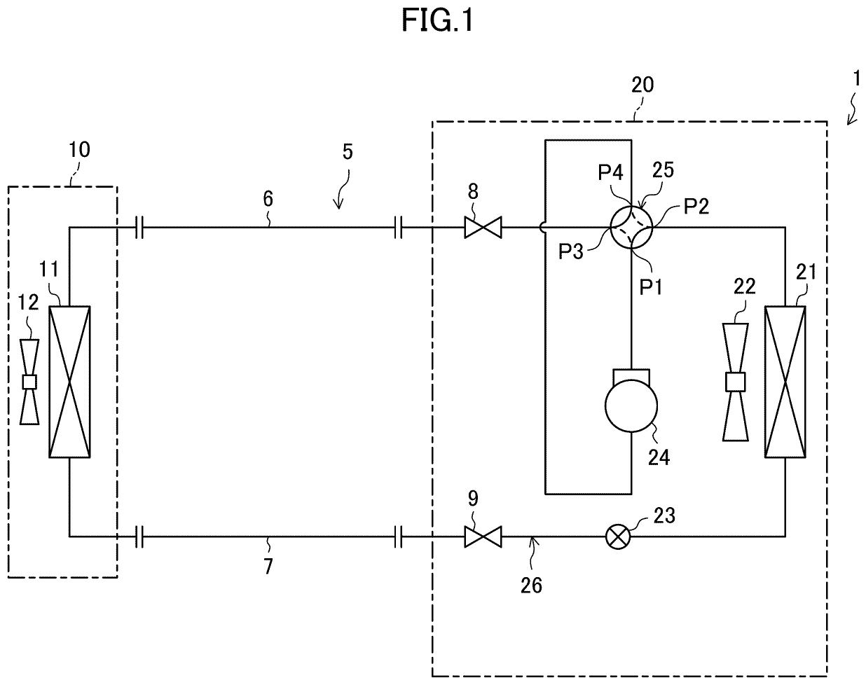

As shown in FIG. 1, the air conditioner (1) includes a refrigerant circuit (5) that circulates a refrigerant to perform a refrigeration cycle. The air conditioner (1) includes an indoor unit (10) and an outdoor unit (20). The indoor unit (10) is placed inside. The outdoor unit (20) is placed outside. The indoor unit (10) and the outdoor unit (20) are connected to each other by a gas pipe (6) and a liquid pipe (7). The gas pipe (6) is connected with a gas shut-off valve (8). The liquid pipe (7) is connected with a liquid shut-off valve (9).

### (2) INDOOR UNIT

The indoor unit (10) includes an indoor heat exchanger (11) and an indoor fan (12). The indoor heat exchanger (11) is, for example, a cross-fin type fin-and-tube heat exchanger. In the indoor heat exchanger (11), the refrigerant flowing inside the heat transfer tube and the air blown by the indoor fan (12) exchange heat.

### (3) OUTDOOR UNIT

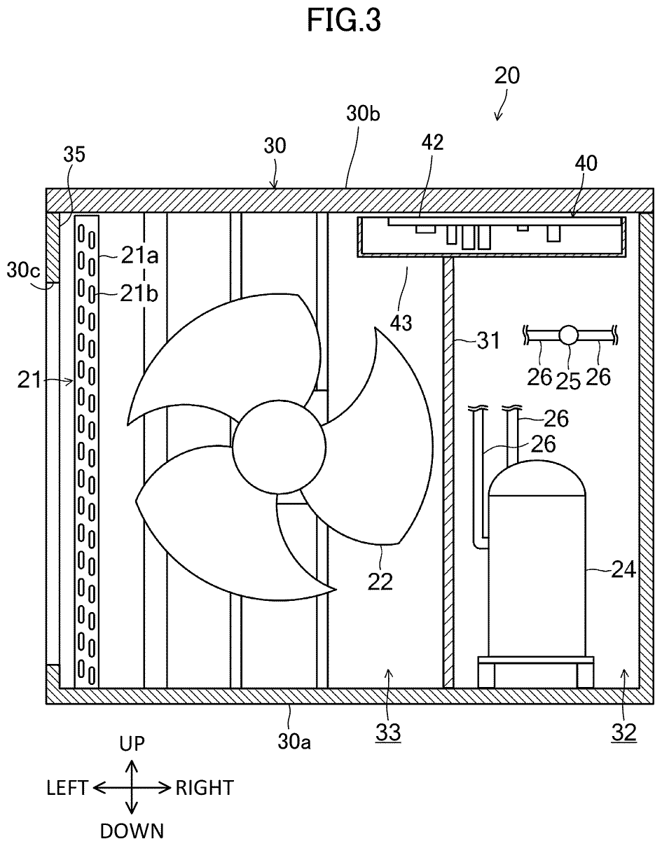

As shown in FIGS. 1 to 3, the outdoor unit (20) includes an outdoor heat exchanger (21), an outdoor fan (22), an outdoor expansion valve (23), a compressor (24), a four-way switching valve (25), and an electric component unit (40). The outdoor heat exchanger (21), the outdoor expansion valve (23), the compressor (24), and the four-way switching valve (25) are connected by a refrigerant pipe (26).

The outdoor heat exchanger (21) is, for example, a cross-fin type fin-and-tube heat exchanger. The outdoor heat exchanger (21) includes a plurality of fins (21a) and a heat transfer tube (21b). The plurality of fins (21a) are spaced in the direction orthogonal to the air flow direction. The heat transfer tube (21b) extends through the fins (21a) in the thickness direction. The heat transfer tube (21b) is disposed through multiple layers in the up-down direction.

In the outdoor heat exchanger (21), the refrigerant flowing inside the heat transfer tube (21b) and the air blown by the outdoor fan (22) exchange heat. The outdoor expansion valve (23) is, for example, an electronic expansion valve.

The compressor (24) is, for example, a rotary compressor such as a scroll compressor. The four-way switching valve (25) switches between a cooling operation and a heating operation. In the cooling operation, a first port (P1) and a second port (P2) of the four-way switching valve (25) communicate with each other, and a third port (P3) and a fourth port (P4) communicate with each other (the state indicated by the solid lines in FIG. 1). In the heating operation, the first port (P1) and the third port (P3) of the four-way switching valve (25) communicate with each other, and the second port (P2) and the fourth port (P4) communicate with each other (the state indicated by the broken lines in FIG. 1).

The outdoor unit (20) includes a casing (30). The casing (30) includes a body casing (30a) and a top panel (30b). The body casing (30a) is formed in a box shape where its upper surface is open. In other words, the upper surface of the body casing (30a) has an opening (35). The top panel (30b) is attached to the body casing (30a) so as to close the opening (35) of the main casing (30a). The top panel (30b) can be attached to and detached from the body casing (30a). The opening (35) of the body casing (30a) is an example of the opening (35) for maintenance of the outdoor unit (20).

In the body casing (30a), a partitioning member (31) extending in the front-back direction and the up-down direction is disposed. The partitioning member (31) partitions the inside of the body casing (30a) into a machine chamber (32) and a fan chamber (33).

In the body casing (30a), the machine chamber (32) is a space located to the right of the partitioning member (31). The compressor (24), the four-way switching valve (25), the refrigerant pipe (26), and the electric component unit (40) are disposed in the machine chamber (32).

In the body casing (30a), the fan chamber (33) is a space located to the left of the partitioning member (31). The outdoor fan (22) and the outdoor heat exchanger (21) are disposed in the fan chamber (33).

The body casing (30a) includes a back sidewall and a left sidewall, each of which is provided with a suction port (30c) communicating with the fan chamber (33). When the outdoor fan (22) is driven, outside air is sucked into the fan chamber (33) through the suction port (30c). The body casing (30a) includes a front sidewall which is provided with an outlet port (30d) communicating with the fan chamber (33). When the outdoor fan (22) is driven, air in the fan chamber (33) is blown out through the outlet port (30d).

### (4) ELECTRIC COMPONENT UNIT

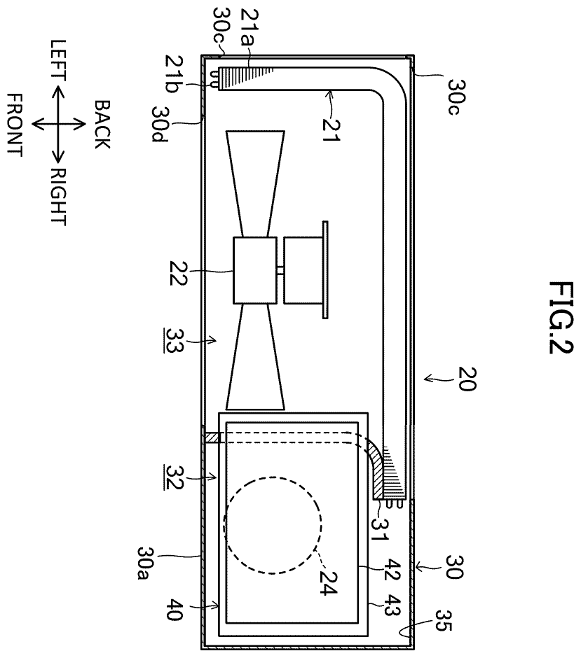

The electric component unit (40) serves as a power converter for supplying power to the motor of the compressor (24). As shown in FIGS. 2 to 4, the electric component unit (40) includes a substrate casing (43), predetermined electric components (41), a substrate (42), and a surface mount LED (46). The electric component unit (40) is disposed near the top panel (30b) above the machine chamber (32).

The substrate casing (43) is a box-shaped member having an opening at its top. The substrate casing (43) houses various electric components (41) including the substrate (42). Only one substrate (42) is disposed in the substrate casing (43) of this embodiment. The opening at the top of the substrate casing (43) faces the lower surface of the top panel (30b).

The electric components (41) are mounted on the substrate (42). The electric components (41) are control circuit components such as power transistors, microcomputer chips for controlling devices, or a memory for storing control programs.

A heat sink (not shown) is provided as a member for reducing temperature increases of the electric components (41) such as power transistors that generate a relatively large amount of heat. The heat sink consists of a metal member.

### (4-1) Substrate

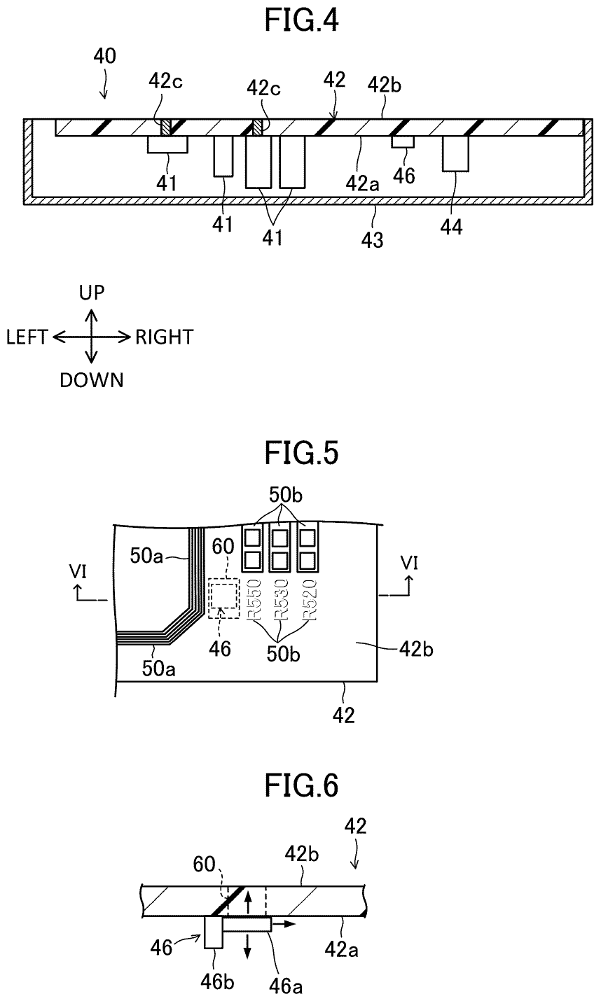

As shown in FIG. 4, the substrate (42) includes a mounting surface (42a) and a pattern surface (42b). The mounting surface (42a) is an example of the first surface (42a). The pattern surface (42b) is an example of the second surface (42b). The substrate (42) is disposed so that the pattern surface (42b) faces the opening (35) of the body casing (30a). In other words, the substrate (42) is disposed so that the pattern surface (42b) faces upward and the mounting surface (42a) faces downward. The substrate (42) of this embodiment is a single layer.

The electric component (41) and the surface mount LED (46) are disposed on the mounting surface (42a). The details of the surface mount LED (46) will be described later. Various connectors (44) are also mounted on the mounting surface (42a). The connectors (44) are used for, for example, connecting an output (AC power) of an inverter circuit (not shown) to a load (motor).

The substrate (42) has a plurality of through holes (hereinafter referred to as through holes (42c)). The through holes (42c) are formed for the purpose of, for example, conducting electricity between the mounting surface (42a) and the pattern surface (42b). Terminals of the electric component (41) are soldered on wiring patterns of the substrate (42).

As shown in FIG. 5, the wiring patterns (50a) are formed on the pattern surface (42b). Various electric components (41) are electrically connected to the wiring patterns (50a), thereby forming a predetermined circuit. Silk (50b) is applied onto the pattern surface (42b). The silk (50b) is a coating material for labeling the pattern surface (42b) with predetermined information such as a part number, a manufacturer logo, and a manufacture date. The wiring pattern (50a) and the silk (50b) are examples of the light transmission reduction material (50a, 50b). The light transmission reduction material (50a, 50b) reduces light transmission between the mounting surface (42a) and the pattern surface (42b).

As shown in FIGS. 5 and 6, the substrate (42) includes a light transmitting region (60). The light transmitting region (60) is a region in which when the pattern surface (42b) is viewed from front, light is transmitted from the mounting surface (42a) to the pattern surface (42b). In other words, the light transmitting region (60) is a region in which a pattern wire or a silk as the light transmission reduction material (50a, 50b) is not provided.

### (4-2) Surface Mount LED

The surface mount LED (46) is a light source for informing a service person about a microcomputer operation, a communication state, an error state, or the like of the substrate (42). The surface mount LED (46) is a chip LED provided on the mounting surface (42a). In this embodiment, when the air conditioner (1) is operating normally, the surface mount LED (46) is blinking. The surface mount LED (46) is an example of the first light source (46).

As shown in FIG. 6, the surface mount LED (46) of this embodiment is a side emitting chip LED. Specifically, the surface mount LED (46) includes a light emitter (46a) and a light emitting substrate (46b).

The light emitter (46a) is a member that emits light of an LED. Specifically, the light emitter (46a) includes an LED element and an encapsulating resin. The LED element is encapsulated in the encapsulating resin. The encapsulating resin is a transparent or translucent resin (silicone, epoxy resin, or the like). The encapsulating resin is formed in a substantially rectangular parallelepiped shape. The light emitting substrate (46b) controls light emission of the LED element of the light emitter (46a). The light emitting substrate (46b) is attached on the mounting surface (42a).

The light emitter (46a) is adjacent to the light emitting substrate (46b) in the direction along the mounting surface (42a). Accordingly, as indicated by the arrows in FIG. 6, the light emitter (46a) emits light toward the mounting surface (42a) and also emits light in the direction along the mounting surface (42a).

The light emitter (46a) is disposed not to overlap the wiring pattern (50a) or the silk (50b) when the pattern surface (42b) is viewed from front. In other words, the surface mount LED (46) emits light toward the light transmitting region (60). Accordingly, part of LED light emitted from the light emitter (46a) is transmitted from the mounting surface (42a) toward the pattern surface (42b), and the light of the surface mount LED is visible when viewed from the pattern surface.

### (5) FEATURES

### (5-1) First Feature

In the outdoor unit (20) of this embodiment, the substrate (42) includes the light transmitting region (60) in which light is transmitted from the mounting surface (42a) (the first surface) toward the pattern surface (42b) (the second surface) when the pattern surface (42b) (the second surface) is viewed from front. The substrate (42) also includes the surface mount LED (46) provided on the mounting surface (42a) and configured to emit light toward the light transmitting region (60).

According to this embodiment, the surface mount LED is mounted as the light source on the mounting surface (42a), and thus the design of the substrate (42) is more flexible than if a lead LED is mounted. Specifically, a lead LED requires two leads connected to the LED and also soldered to the pattern surface (42b) via the through holes (42b). Then, a slit (recess) is formed on part of the mounting surface (42a) that faces the LED (specifically, a position between the two leads) to enable LED light to transmit more easily, so that the substrate (42) is locally thinner. If a lead LED is used as a light source in this manner, the available areas of the mounting surface (42a) and the pattern surface (42b) are smaller, and the design is less flexible. However, if the surface mount LED (46) is used, soldering on the pattern surface (42b) can be omitted, and also no slit needs to be provided and thus the surface of the substrate (42) can be used more effectively.

In addition, since the light of the surface mount LED (46) emitted to the light transmitting region (60) is transmitted through the substrate (42) in the thickness direction, the light of the surface mount LED (46) is visible when viewed from the pattern surface (42b). Accordingly, the state of light of the surface mount LED (46) can be checked by simply opening the top panel (30b) of the outdoor unit (20). As a result, a service person can easily check a microcomputer operation, a communication state, or an error state of the substrate (42).

### (5-2) Second Feature

In the outdoor unit (20) of this embodiment, the light transmitting region (60) is a region in which the wiring pattern (50a) and the silk (50b) (the light transmission reduction material) that reduce light transmission between the mounting surface (42a) and the pattern surface (42b) are not provided.

According to this embodiment, in the light transmitting region (60), the wiring pattern (50a) and the silk are not provided. Thus, when light of the surface mount LED (46) is emitted to that region, light is visible from the pattern surface (42b).

### (5-3) Third Feature

In the outdoor unit (20) of this embodiment, the surface mount LED (46) is a side emitting chip LED. The light emitted from the light emitter (46a) of the side emitting LED toward the mounting surface (42a) can be transmitted through the substrate (42) in the thickness direction. In addition, the LEDs of the outdoor unit (20) can consist of only the side emitting chip LEDs. Thus, it is unnecessary to use different types of LEDs particularly for the LEDs provided on the substrate (42), and the manufacturing costs and the complex management of the components can be reduced.

### (6) VARIATIONS

Variations of the outdoor unit (20) of the present disclosure will be described. Configurations different from those of the embodiment will be described.

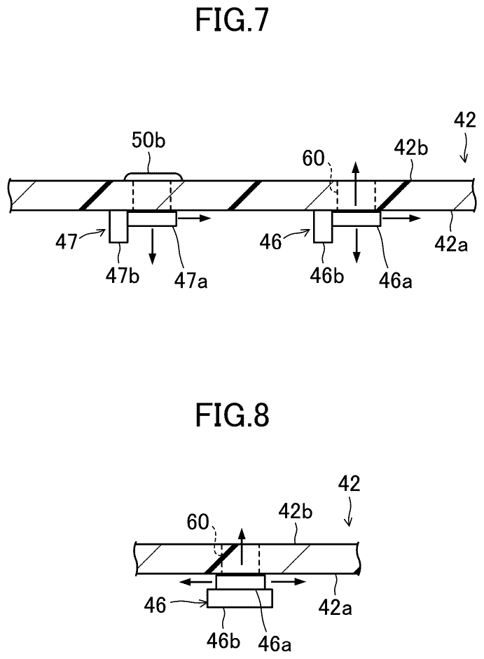

As shown in FIG. 7, two surface mount LEDs (46, 47) are mounted on the mounting surface (42a) of the substrate (42) of this example. One of the surface mount LEDs is referred to as a first surface mount LED (46), and the other one of the surface mount LEDs is referred to as a second surface mount LED (47). The first surface mount LED (46) and the second surface mount LED (47) are spaced apart from each other at a predetermined distance. The first surface mount LED (46) is an example of the first light source (46). The second surface mount LED (47) is an example of the second light source (47). The first surface mount LED (46) and the second surface mount LED (47) have the same configuration as those of the side emitting LED of the embodiment. The second surface mount LED (47) includes a light emitter (47a) and a light emitting substrate (47b).

The first surface mount LED (46) is a light source for informing a service person about a microcomputer operation, a communication state, an error state, or the like of the substrate (42). The second surface mount LED (47) is a light source for an operator to check the quality of the substrate (42) in the manufacturing process of the substrate (42), for example. That is, the second surface mount LED (47) is a light source that a service person does not need to check.

The substrate (42) of this example includes a light transmission reduction material (50a, 50b) that reduces transmission of light toward the mounting surface (42a) of the second surface mount LED (47). Specifically, the light transmission reduction material is a silk (50b) applied onto the pattern surface (42b). The silk (50b) is applied to part of the pattern surface (42b) on which the second surface mount LED (47) is disposed.

Accordingly, even if the second surface mount LED (47) emits light, the silk (50b) reduces transmission of light toward the mounting surface (42a) through the substrate (42) (see the arrow in FIG. 7). Accordingly, a service person can visually check the first surface mount LED (46) only, and does not mistake the light of the first surface mount LED (46) for the light of the second surface mount LED (47).

### (7) OTHER EMBODIMENTS

The above embodiment and variations may be configured as follows.

As shown in FIG. 8, the surface mount LED (46) may be a back emitting chip LED. In the back emitting LED, the light emitter (46a) is disposed between the light emitting substrate (46b) and the mounting surface (42a). The light emitting substrate (46b) is conductively connected to the substrate (42). The light emitter (46a) emits light toward the mounting surface (42a) and along the mounting surface (42a) (see the arrows in FIG. 8). Part of the light toward the mounting surface (42a) passes through the light transmitting region. That is, even the back emitting chip LED enables light transmitted through the substrate (42) to be visible from the pattern surface (42b).

The substrate (42) may be comprised of a plurality of substrates (42). In this case, the light transmitting region (60) is a region in which light is transmitted through layers. In other words, the light transmitting region (60) is a region in which the wiring pattern (50a) and the silk (50b) are not provided in each layer. Thus, even the multilayer substrate (42), where the surface mount LED (46) is disposed on part of the mounting surface (42a) that corresponds to the light transmitting region (60), enables LED light to be visible from the back surface (pattern surface (42b)) of the mounting surface (42a).

In the variation, the light transmission reduction material (50a, 50b) may be the wiring pattern (50a). Specifically, the second surface mount LED (47) may be disposed on the back surface (mounting surface (42a)) of the wiring pattern (50a). Accordingly, light from the second surface mount LED (47) toward the substrate (42) is less transmitted through the substrate (42) by the wiring pattern (50a).

While the embodiment and variations thereof have been described above, it will be understood that various changes in form and details may be made without departing from the spirit and scope of the claims. The embodiment and the variations thereof may be combined and replaced with each other without deteriorating intended functions of the present disclosure. The expressions of “first,” “second,” . . . described above are used to distinguish the terms to which these expressions are given, and do not limit the number and order of the terms.

As described above, the present disclosure is useful for an outdoor unit.

1. An outdoor unit of an air conditioner, comprising:
a casing having an opening for maintenance; and
a substrate disposed in the casing and including
a first surface on which an electric component is disposed, and
a second surface facing the opening,
the substrate including
a light transmitting region in which light is transmitted from the first surface toward the second surface when the second surface is viewed from a front, and
a first light source provided on the first surface,
the first light source being a surface mount LED that emits light toward the light transmitting region.

2. The outdoor unit of claim 1, wherein
the light transmitting region is a region in which a light transmission reduction material, which reduces light transmission between the first surface and the second surface, is not provided.

3. The outdoor unit of claim 1, wherein
the first light source includes
a light emitter including an LED element, and
a light emitting substrate provided on the first surface and configured to control light emission of the LED element, and
the light emitter is adjacent to the light emitting substrate in a direction along the first surface.

4. The outdoor unit of claim 2, wherein
the first light source includes
a light emitter including an LED element, and
a light emitting substrate provided on the first surface and configured to control light emission of the LED element, and
the light emitter is adjacent to the light emitting substrate in a direction along the first surface.

5. The outdoor unit of claim 1, wherein
the first light source includes
a light emitter including an LED element, and
a light emitting substrate provided on the first surface and configured to control light emission of the LED element, and
the light emitter is disposed between the first surface and the light emitting substrate.

6. The outdoor unit of claim 2, wherein
the first light source includes
a light emitter including an LED element, and
a light emitting substrate provided on the first surface and configured to control light emission of the LED element, and
the light emitter is disposed between the first surface and the light emitting substrate.

7. The outdoor unit of claim 1, further comprising:
a second light source disposed on the first surface at a predetermined distance from the first light source and configured to emit light toward the first surface; and
a light transmission reduction material that reduces light transmission between the first surface and the second surface,
the light transmission reduction material reducing transmission of light between the first surface and the second surface, where the light is emitted from the second light source.

8. The outdoor unit of claim 2, further comprising:
a second light source disposed on the first surface at a predetermined distance from the first light source and configured to emit light toward the first surface; and
a light transmission reduction material that reduces light transmission between the first surface and the second surface,
the light transmission reduction material reducing transmission of light between the first surface and the second surface, where the light is emitted from the second light source.

9. The outdoor unit of claim 3, further comprising:
a second light source disposed on the first surface at a predetermined distance from the first light source and configured to emit light toward the first surface; and
a light transmission reduction material that reduces light transmission between the first surface and the second surface,
the light transmission reduction material reducing transmission of light between the first surface and the second surface, where the light is emitted from the second light source.

10. The outdoor unit of claim 5, further comprising:
a second light source disposed on the first surface at a predetermined distance from the first light source and configured to emit light toward the first surface; and
a light transmission reduction material that reduces light transmission between the first surface and the second surface,
the light transmission reduction material reducing transmission of light between the first surface and the second surface, where the light is emitted from the second light source.
